(19) United States
(12) Patent Application Publication
(10) Pub. No.: US 2021/0362290 A1
(43) Pub. Date: Nov. 25, 2021

(54) PROCESSING APPARATUS, PROCESSING METHOD AND COMPUTER- READABLE RECORDING MEDIUM

(71) Applicant: Tokyo Electron Limited, Tokyo (JP)

(72) Inventors: Tomohiro KANEKO, Koshi City, Kumamoto (JP); Takeshi MATSUMOTO, Koshi City, Kumamoto (JP); Nobutaka FUKUNAGA, Koshi City, Kumamoto (JP); Masakazu YARIMITSU, Koshi City, Kumamoto (JP); Hidejiro RYU, Koshi City, Kumamoto (JP)

(21) Appl. No.: 17/257,042

(22) PCT Filed: Jun. 25, 2019
(86) PCT No.: PCT/JP2019/025153

§ 371 Date: Dec. 30, 2020

(30) Foreign Application Priority Data
Jul. 9, 2018 (JP) 2018-129803

(51) Int. Cl. B24B 37/005; B24B 37/34

(52) U.S. Cl. CPC B24B 37/005; H01L 21/02013; B24B 37/345

(57) ABSTRACT

A processing apparatus includes a holder configured to hold a substrate; a grinding device configured to perform a grinding on a processing surface of the substrate held on the holder; a transfer device configured to transfer the substrate to the holder; and a controller configured to control the holder, the grinding device and the transfer device. The controller controls the holder, the grinding device and the transfer device to perform performing initialization of the holder, initialization of the grinding device and initialization of the transfer device after the processing apparatus is stopped during an operation thereof and the processing apparatus is restarted; detecting the substrate on the holder; deciding whether the grinding on the detected substrate by the grinding device is required; and performing, by the grinding device, the grinding on the processing surface of the substrate on which the grinding is decided to be required.

### TECHNICAL FIELD

The various aspects and embodiments described herein pertain generally to a processing apparatus, a processing method and a computer-readable recording medium.

### BACKGROUND

Patent Document 1 discloses an operating method of a grinding device that grinds a rear surface of a wafer. The grinding device is equipped with a position alignment device for centering the wafer, a chuck table for attracting and holding the wafer, a grinding device for grinding the wafer held on the chuck table and a cleaning device for cleaning the wafer. In the grinding device, when a control device executes an automatic grinding program, the wafer is sequentially moved from the position alignment device to the chuck table and the cleaning device to be subjected to respective processings. Further, if the control device receives a signal to stop the automatic grinding program during the execution of the automatic grinding program, the control device determines whether a grinding process has been performed on the wafer. If it is determined that the grinding process has been performed, the wafer is moved along the same path as that of the automatic grinding program and then accommodated in a cassette. If it is determined that the grinding process has not been performed, the wafer is moved along a path in the reverse order to that of the automatic grinding program and then accommodated in the cassette.

### PRIOR ART DOCUMENT

Patent Document 1: Japanese Patent Laid-open Publication No. 2011-218472

### DISCLOSURE OF THE INVENTION

In view of the foregoing, after a substrate processing apparatus is stopped during an operation and then restarted, the substrate processing apparatus performs an appropriate processing to a substrate which has been processed before the substrate processing apparatus is stopped.

### Means for Solving the Problems

In one exemplary embodiment, a processing apparatus includes a holder configured to hold a substrate; a grinding device configured to perform a grinding on a processing surface of the substrate held on the holder; a transfer device configured to transfer the substrate to the holder; and a controller configured to control the holder, the grinding device and the transfer device. The controller controls the holder, the grinding device and the transfer device to perform performing initialization of the holder, initialization of the grinding device and initialization of the transfer device after the processing apparatus is stopped during an operation thereof and the processing apparatus is restarted; detecting the substrate on the holder; deciding whether the grinding on the detected substrate by the grinding device is required; and performing, by the grinding device, the grinding on the processing surface of the substrate on which the grinding is decided to be required.

According to the present disclosure, after the processing apparatus of the substrate is stopped during the operation thereof and the processing apparatus is restarted, the appropriate processing can be performed on the substrate obtained before the processing apparatus is stopped.

### BRIEF DESCRIPTION OF THE DRAWINGS

FIG. 1 is a schematic plan view illustrating a configuration of a processing apparatus according to a present exemplary embodiment.

FIG. 2 is a schematic side view illustrating a configuration of an inspection unit.

FIG. 3 is a flowchart showing main processes of a processing.

FIG. 4 is a flowchart showing main processes of an operating preparation in the processing.

FIG. 5 is an explanatory diagram showing timings to initialize individual units of the processing apparatus.

FIG. 6 is an explanatory diagram showing a flow of an after-restart grinding on a wafer.

### DETAILED DESCRIPTION

In a manufacturing process for a semiconductor device, a semiconductor wafer (hereinafter, referred to as “wafer”) having devices, e.g., a plurality of electronic circuits on a front surface thereof is thinned by grinding a rear surface of the wafer.

The rear surface of the wafer is ground by means of, for example, the grinding device disclosed in Patent Document 1. As described above, in this grinding device, if the control device receives the signal to stop the automatic grinding program, the control device determines whether a grinding process has been performed on the wafer, and a transfer path of the wafer is determined depending on the result of determination.

As for the grinding device disclosed in Patent Document 1, efficient recovery of the wafer in response to a command to stop the grinding is considered. However, from when the grinding device is restarted to when a normal operation is performed, appropriate handling of the wafer remaining after the grinding device is stopped is not considered.

According to the technique of the present disclosure, after the processing apparatus is stopped and then restarted, an operating preparation of the processing apparatus is appropriately performed. Hereinafter, a processing apparatus and a processing method according to the present exemplary embodiment will be described with reference to the accompanying drawings. Further, in the present specification and drawings, elements that have substantially the same function and structure are denoted with the same reference numeral, and repeated explanation is omitted.

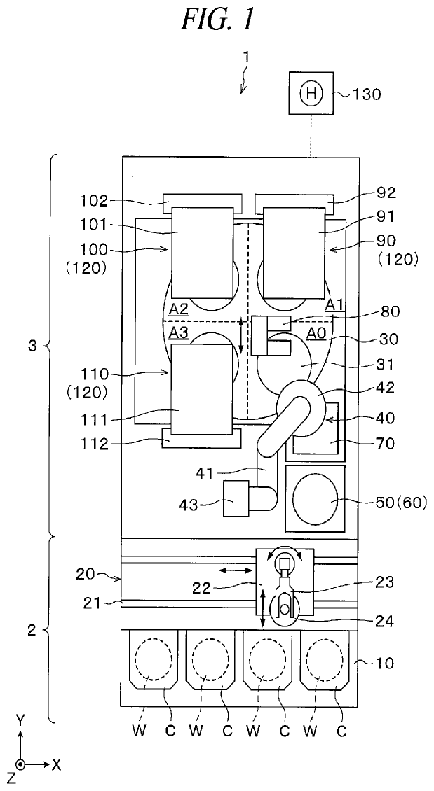

First, a configuration of the processing apparatus according to the present exemplary embodiment will be described. FIG. 1 is a schematic plan view illustrating a configuration of a processing apparatus 1.

In the processing apparatus 1 according to the present exemplary embodiment, a wafer W as a substrate is thinned. The wafer W is a semiconductor wafer such as a silicon wafer or a compound semiconductor wafer. A device (not shown) is formed on a front surface (hereinafter, referred to as “non-processing surface Wn”) of the wafer W and a protective member, such as a protective tape (not shown), for protecting the device is attached to the non-processing surface Wn. Also, the wafer W is thinned by performing a predetermined processing such as grinding on a rear surface (hereinafter, referred to as “processing surface Wg”) of the wafer W.

As shown in FIG. 1, the processing apparatus 1 includes a carry-in/out station 2 to/from which a cassette C accommodating therein a plurality of wafers W is transferred from/to, for example, the outside and a processing station 3 configured to perform predetermined processings on the wafers W, and the carry-in/out station 2 and the processing station 3 are connected as one body. The carry-in/out station 2 and the processing station 3 are arranged in a Y-axis direction.

In the carry-in/out station 2, a cassette placing table 10 is provided. In the illustrated example, a plurality of; for example, four cassettes C can be arranged in a row in an X-axis direction on the cassette placing table 10.

Further, in the carry-in/out station 2, for example, a wafer transfer section 20 is provided adjacent to the cassette placing table 10 in a positive Y-axis direction. The wafer transfer section 20 is equipped with a wafer transfer device 22 configured to be movable along a transfer path 21 extending in the X-axis direction. The wafer transfer device 22 has a transfer fork 23 and a transfer pad 24 that hold the wafer W. A tip end of the transfer fork 23 is branched into two tip end portions to attract and hold the wafer W. The transfer fork 23 transfers the wafer W before being ground. The transfer pad 24 is of a circular shape having a larger diameter than the wafer W when viewed from the top, and attracts and holds the wafer W. The transfer pad 24 transfers, for example, the wafer W after being ground. Further, each of the transfer fork 23 and the transfer pad 24 is movable in a horizontal direction, in a vertical direction, around a horizontal axis and around a vertical axis.

In the processing station 3, processings such as grinding and cleaning are performed consecutively on the wafer W. The processing station 3 includes a turntable 30, a transfer unit 40 as a transfer device, an alignment unit 50, a first cleaning unit 60, a second cleaning unit 70, a third cleaning unit 80, a rough grinding unit 90 as a grinding device, an intermediate grinding unit 100 as a grinding device, a finish grinding unit 110 as a grinding device, and an inspection unit 120.

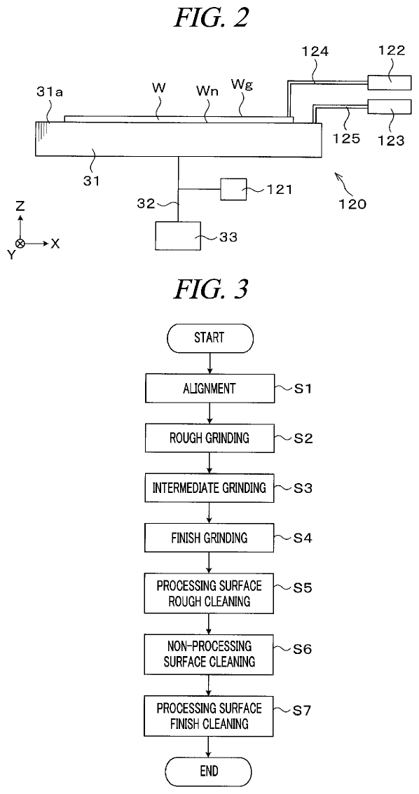

The turntable 30 is configured to be rotatable by a rotating mechanism (not illustrated). Four chucks 31 serving as holders configured to attract and hold the wafer W are provided on the turntable 30. The chucks 31 are arranged concentrically with the turntable 30 at the same angular interval, i.e., every 90 degrees. The four chucks 31 are configured to be movable to a delivery position A0 and processing positions A1 to A3 when the turntable 30 is rotated. Further, for example, a porous chuck (vacuum chuck) may be used as the chuck 31. As shown in FIG. 2, the chuck 31 is connected to a suction source 33 configured to evacuate the wafer W via a suction pipe 32. Also, the chuck 31 is held on a chuck base (not shown) and configured to be rotatable by a rotation mechanism (not shown).

As shown in FIG. 1, in the present exemplary embodiment, the delivery position A0 refers to a position on the positive side of the X-axis direction and the negative side of the Y-axis direction of the turntable 30, and the third cleaning unit 80 is placed at the delivery position A0. On the negative side of the Y-axis direction of the delivery position A0, the second cleaning unit 70, the alignment unit 50 and the first cleaning unit 60 are arranged. The alignment unit 50 and the first cleaning unit 60 are stacked in this order from above. The first processing position A1 refers to a position on the positive side of the X-axis direction and the positive side of the Y-axis direction of the turntable 30, and the rough grinding unit 90 is placed at the first processing position A1. The second processing position A2 refers to a position on the negative side of the X-axis direction and the positive side of the Y-axis direction of the turntable 30, and the intermediate grinding unit 100 is placed at the second processing position A2. The third processing position A3 refers to a position on the negative side of the X-axis direction and the negative side of the Y-axis direction of the turntable 30, and the finish grinding unit 110 is placed at the third processing position A3.

The transfer unit 40 is a multi-joint robot having a plurality of, for example, three arms 41. Each of the three arms 31 is configured to be pivotable. An arm 41 at a tip end is equipped with a transfer pad 42 configured to attract and hold the wafer W. Also, an arm 41 at a base end is provided at a lift mechanism 43 configured to move the arm 41 in the vertical direction. Further, the transfer unit 40 having the configuration as described above may transfer the wafer W to the delivery position A0, the alignment unit 50, the first cleaning unit 60 and the second cleaning unit 70.

In the alignment unit 50, an orientation of the horizontal direction of the wafer W before being ground is adjusted. For example, while the wafer W held on a spin chuck (not shown) is rotated, a position of a notch of the wafer W is detected by a detector (not shown) to adjust the position of the notch and thus to adjust the orientation of the horizontal direction of the wafer W.

In the first cleaning unit 60, the processing surface Wg of the wafer W after being ground is cleaned and more specifically spin-cleaned.

In the second cleaning unit 70, the non-processing surface Wn of the wafer W after being ground, which is held on the transfer pad 42, is cleaned, and the transfer pad 42 is also cleaned.

In the third cleaning unit 80, the processing surface Wg of the wafer W after being ground is cleaned, and the chuck 31 is cleaned.

In the rough grinding unit 90, rough grinding is performed on the processing surface Wg of the wafer W. The rough grinding unit 90 has a rough grinder 91 equipped with an annular rough grinding whetstone (not shown) which is rotatable. Also, the rough grinder 91 is configured to be movable in the vertical direction and the horizontal direction along a column 92. Further, in a state where the processing surface Wg of the wafer W held on the chuck 31 is in contact with the rough grinding whetstone, each of the chuck 31 and the rough grinding whetstone is rotated and the rough grinding whetstone is moved down to perform the rough grinding on the processing surface Wg of the wafer W.

In the intermediate grinding unit 100, intermediate grinding is performed on the processing surface Wg of the wafer W. The intermediate grinding unit 100 has an intermediate grinder 101 equipped with an annular intermediate grinding whetstone (not shown) which is rotatable. Also, the intermediate grinder 101 is configured to be movable in the vertical direction and the horizontal direction along a column 102. Further, a particle size of abrasive grains of the intermediate grinding whetstone is smaller than that of the rough grinding whetstone. Furthermore, in a state where the processing surface Wg of the wafer W held on the chuck 31 is in contact with the intermediate grinding whetstone, each of the chuck 31 and the intermediate grinding whetstone is rotated and the intermediate grinding whetstone is moved down to perform the intermediate grinding on the processing surface Wg of the wafer W.

In the finish grinding unit 110, finish grinding is performed on the processing surface Wg of the wafer W. The finish grinding unit 110 has a finish grinder 111 equipped with an annular finish grinding whetstone (not shown) which is rotatable. Also, the finish grinder 111 is configured to be movable in the vertical direction and the horizontal direction along a column 112. Further, a particle size of abrasive grains of the finish grinding whetstone is smaller than that of the intermediate grinding whetstone. Furthermore, in a state where the processing surface Wg of the wafer W held on the chuck 31 is in contact with the finish grinding whetstone, each of the chuck 31 and the finish grinding whetstone is rotated and the finish grinding whetstone is moved down to perform the finish grinding on the processing surface Wg of the wafer W.

The inspection unit 120 is provided at the delivery position A0 and each of the processing positions A1 to A3. Also, as shown in FIG. 2, the inspection unit 120 is equipped with a pressure sensor 121 as a detector. The pressure sensor 121 is provided at the suction pipe 32 to measure a suction pressure of the suction source 33. Further, the inspection unit 120 may use the suction pressure measured by the pressure sensor 121 to detect whether there is the wafer W.

Also, the inspection unit 120 is equipped with a first height gauge 122 configured to measure a height of the processing surface Wg of the wafer W and a second height gauge 123 configured to measure a height of a front surface 31a of the chuck 31. The first height gauge 122 includes a sensor 124, and when a tip end of the sensor 124 is in contact with the processing surface Wg of the wafer W, the height position of the processing surface Wg is measured. The second height gauge 123 includes a sensor 125, and when a tip end of the sensor 125 is in contact with the front surface 31a of the chuck 31, the height position of the front surface 31a is measured. Further, the inspection unit 120 can measure the thickness of the wafer W. Furthermore, the configuration of the inspection unit 120 is not limited to the present exemplary embodiment, but can be arbitrarily employed as long as it can detect the wafer W. For example, the inspection unit may use a non-contact sensor to detect the wafer W.

As shown in FIG. 1, the processing apparatus 1 is equipped with a controller 130. The controller 130 is, for example, a computer and has a program storage unit (not shown). The program storage unit stores a program which controls a processing on the wafer W in the processing apparatus 1. The program storage unit also stores a program that controls operations of a driving system, such as the above-described various processing units and transfer devices, to implement the following processing in the processing apparatus 1. Also, the program may be stored in a computer-readable recording medium H and installed from the recording medium H into the controller 130.

Hereinafter, a processing to be performed in the processing apparatus 1 will be described.

A cassette C accommodating the wafers W therein is placed on the cassette placing table 10 of the carry-in/out station 2. In the cassette C, each wafer W is accommodated such that the non-processing surface Wn of the wafer W faces upwards in order to suppress the deformation of the protective tape.

Then, a wafer W is taken out from the cassette C by the transfer fork 23 of the wafer transfer device 22 and then transferred into the processing station 3. Here, the front and rear surfaces of the wafer W are reversed by the transfer fork 23 such that the processing surface Wg of the wafer W faces upwards.

The wafer W transferred into the processing station 3 is delivered to the alignment unit 50. Then, in the alignment unit 50, the orientation in the horizontal direction of the wafer W is adjusted (process S1 in FIG. 3).

Then, the wafer W is transferred by the transfer unit 40 from the alignment unit 50 to the delivery position A0 to be delivered to the chuck 31 at the delivery position A0. Thereafter, the chuck 31 is moved to the first processing position A1. Then, the rough grinding is performed on the processing surface Wg of the wafer W by the rough grinding unit 90 (process S2 in FIG. 3).

Then, the chuck 31 is moved to the second processing position A2. Thereafter, the intermediate grinding is performed on the processing surface Wg of the wafer W by the intermediate grinding unit 100 (process S3 in FIG. 3).

Then, the chuck 31 is moved to the third processing position A3. Thereafter, the finish grinding is performed on the processing surface Wg of the wafer W by the finish grinding unit 110 (process S4 in FIG. 3).

Then, the chuck 31 is moved to the delivery position A0. Thereafter, rough cleaning is performed on the processing surface Wg of the wafer W by the third cleaning unit 80 (process S5 in FIG. 3). In this process S5, the cleaning is performed to clear contaminants on the processing surface Wg to a certain level.

Then, the wafer W is transferred by the transfer unit 40 from the delivery position A0 to the second cleaning unit 70. Further, in the second cleaning unit 70, the non-processing surface Wn of the wafer W is cleaned to be dried in a state where the wafer W is held on the transfer pad 42 (process S6 in FIG. 3).

Then, the wafer W is transferred by the transfer unit 40 from the second cleaning unit 70 to the first cleaning unit 60. Thereafter, in the first cleaning unit 60, finish cleaning is performed on the processing surface Wg of the wafer W with a cleaning solution (process S7 in FIG. 3). In the process S7, the processing surface Wg is cleaned to a desired degree of cleanliness to be dried.

Then, the wafer W on which all the processings are performed is transferred to the cassette C on the cassette placing table 10 by the transfer pad 24 of the wafer transfer device 22. In this way, a series of processings in the processing apparatus 1 is ended.

Hereinafter, an operating preparation method of the processing apparatus 1 from when the processing apparatus 1 is stopped during an operation and then restarted to when a normal operation is performed will be described.

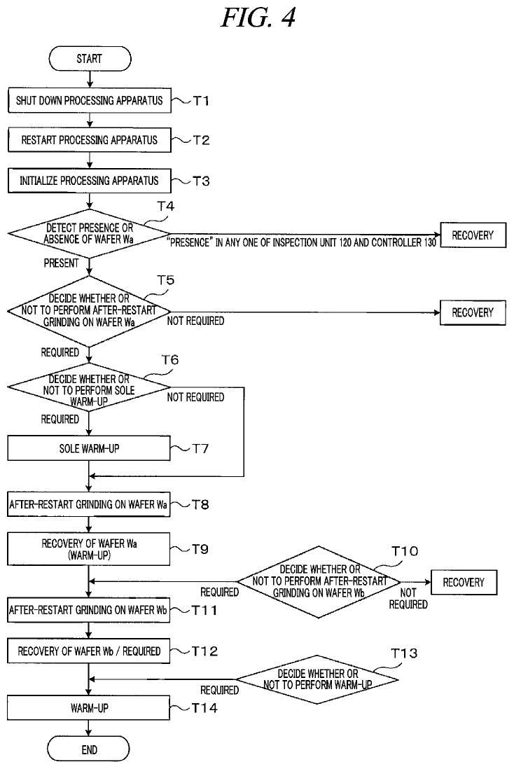

First, while the processing apparatus 1 performs the processing to the wafer W as described above, an abnormality may occur in, for example, any one of the units in the processing apparatus 1. In this case, the processing apparatus 1 is stopped and shut down (process T1 in FIG. 4).

In this process T1, the wafer W may remain in the processing apparatus 1. Therefore, the controller 130 stores the state of the wafer W, for example, the position and the processing state of the wafer W, when the processing apparatus 1 is shut down. For example, in the turntable 30, whether the wafer W is held on the chuck 31 at the delivery position A0 and each of the processing positions A1 to A3 is detected, and to be stored in the controller 130. Further, if the wafer W is held on the chuck 31 at the processing positions A1 to A3, a grinding recipe applied to the wafer W is also stored in the controller 130. The grinding recipe is for when the processing apparatus 1 is shut down, i.e., has been used before the shutdown. Even if the wafer W is placed in another unit, for example, the alignment unit 50, the position and the processing state of the wafer W are stored in the controller 130. In the following description, for convenience in explanation, the wafer W on the chuck 31 of the turntable 30 may be referred as “wafer Wa” and the wafer W in the alignment unit 50 may be referred to as “wafer Wb”.

Then, the processing apparatus 1 is restarted (process T2 in FIG. 4).

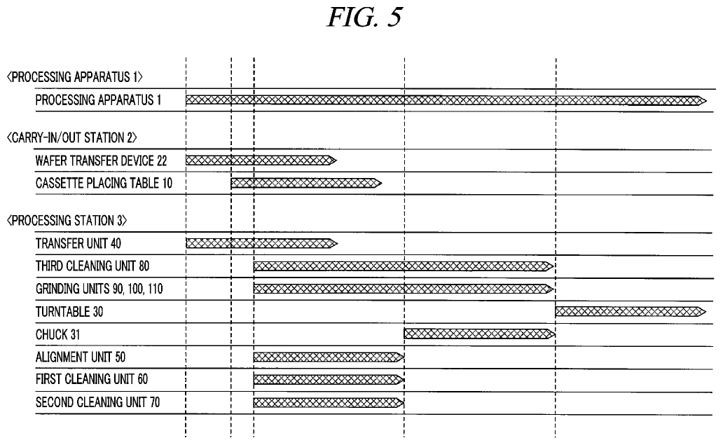

Thereafter, each unit of the processing apparatus 1 is initialized (process T3 in FIG. 4). As shown in FIG. 5, the initialization is sequentially performed according to the function of each unit in the processing apparatus 1. The initialization is performed to return each unit to its original state and to place each unit in an operable state. Further, in FIG. 5, the horizontal axis represents time, and in an arrow for each unit, the base end (left end) indicates initialization start timing and the tip end (right end) indicates initialization end timing.

Initialization of the carry-in/out station 2 will be described. First, in the carry-in/out station 2, initialization of the wafer transfer device 22 is started. Specifically, the horizontal axes of the transfer fork 23 and the transfer pad 24 are initialized. For example, if the processing apparatus 1 is shut down with the transfer fork 23 entering the cassette C or the alignment unit 50, the initialization is performed by taking the transfer fork 23 out of the cassette C or the alignment unit 50 and returning it back to its original position.

In the initialization of the wafer transfer device 22, after the transfer fork 23 and the transfer pad 24 are retreated from the cassette C, initialization of the cassette placing table 10 is subsequently started. Specifically, the cassette placing table 10 is returned back to its original state such as by returning a shutter (not shown) provided in the cassette C to its original position.

Hereinafter, initialization of the processing station 3 will be described. First, in the processing station 3, initialization of the transfer unit 40 is started in parallel with the above-described initialization of the wafer transfer device 22. Specifically, the horizontal axis of the transfer pad 42 is initialized. For example, if the processing apparatus 1 is shut down with the transfer pad 42 entering an accessible unit (for example, the alignment unit 50), the initialization is performed by taking the transfer pad 42 out of the alignment unit 50 and returning it back to its original position.

In the initialization of the transfer unit 40, after the transfer pad 42 is retreated from the corresponding unit, initialization of the third cleaning unit 80 and the grinding units 90, 100 and 110 is subsequently started. That is, initialization of each unit provided above the turntable 30 is performed. Specifically, the third cleaning unit 80 is retreated vertically upwards from a cleaning position; and the third cleaning unit 80 itself is initialized. Further, each of the grinders 91, 101 and 111 is retreated vertically upwards from a grinding position, and the grinding units 90, 100 and 110 themselves are initialized.

When all of the third cleaning unit 80 and the grinders 91, 101 and 111 are retreated, initialization of the four chucks 31 is performed. Further, after the initialization of the four chucks 31 is completed, initialization of the turntable 30 is performed.

Furthermore, in the initialization of the transfer unit 40, after the transfer pad 42 is retreated from the corresponding unit, initialization of the alignment unit 50 and the cleaning units 70 and 80 is performed in parallel with the initialization of the third cleaning unit 80 and the grinding units 90, 100, and 110. Since the wafer transfer device 22 and the transfer unit 40 access the alignment unit 50 and the first cleaning unit 60, all of the transfer fork 23, the transfer pad 24 and the transfer pad 42 need to be retreated.

Along with the initialization of each unit of the processing apparatus 1, the wafer Wa on the chuck 31 of the turntable 30 is detected (process T4 in FIG. 4). The detection of the wafer Wa in the process T4 may be performed after the restart in the process T2 or may be performed in parallel with the initialization of the processing apparatus 1 in the process T3 as in the present exemplary embodiment. Otherwise, the detection of the wafer Wa in the process T4 may be performed during or after the corresponding initialization.

In the process T4, the wafer Wa on the chuck 31 at the delivery position A0 and the processing positions A1 to A3 is detected using the inspection unit 120 (the pressure sensor 121). Then, the presence or absence of the wafer Wa on the chuck 31 is checked based on the wafer Wa detected by the inspection unit 120 and the state of the wafer Wa stored in the controller 130 when the processing apparatus 1 is shut down in the process T1.

For example, as for one chuck 31, if the controller 130 stores “presence” for the wafer Wa and the inspection unit 120 also detects that the wafer Wa is “present”, it is determined that the wafer Wa is held on the chuck 31. Then, the wafer Wa is subjected to a recovery or an after-restart grinding, which will be described later. In the present exemplary embodiment, the after-restart grinding refers to performing the grinding on the wafer Wa, which remains in the processing apparatus 1 before the shutdown, after the restart. For example, the after-restart grinding includes re-grinding the wafer Wa which is shut down while being ground, or grinding the wafer Wa which is shut down before or after being ground.

If the controller 130 stores “presence” for the wafer Wa but the inspection unit 120 detects that the wafer Wa is “absent”, whether the wafer Wa is actually held on the chuck 31 is checked. For example, when the wafer Wa is not present on the chuck 31 such as when an operator has already recovered the wafer Wa, it is determined that the wafer Wa is not present, so that the subsequent processing is not performed. On the other hand, when the wafer Wa remains on the chuck 31 for some reason, the grinders 91, 101 and 111 are retreated in the vertical direction and then, the operator recovers the wafer Wa.

If the controller 130 stores “absence” for the wafer Wa but the inspection unit 120 detects that the wafer Wa is “present”, the operator recovers the wafer Wa. As will be described later, the after-restart grinding of the wafer Wa is performed based on the grinding recipe applied to the wafer Wa before the processing apparatus 1 is shut down. However, in the above-described case, the grinding recipe is not stored in the controller 130. In this state, if the after-restart grinding is performed on the wafer Wa after the processing apparatus 1 is restarted, the wafer Wa may not be appropriately ground. In such a case, the processing apparatus 1 may be damaged, and, thus, the operator recovers the wafer Wa.

If the controller 130 stores “absence” for the wafer Wa and the inspection unit 120 also detects that the wafer Wa is “absent”, it is determined that the wafer Wa is not held on the chuck 31. In such a case, after the initialization in the process T3 is completed, the corresponding chuck 31 becomes usable.

As described above, in the process T4, the presence or absence of the wafer Wa is detected using both the controller 130 and the inspection unit 120, and, thus, the detection accuracy can be improved and the subsequent processing can be appropriately performed.

Then, if it is determined in the process T4 that the wafer Wa is held on the chuck 31, whether to perform the after-restart grinding on the wafer Wa or whether to recover the wafer Wa without performing the after-restart grinding is decided (process T5 in FIG. 4). Whether or not to perform the after-restart grinding on the wafer Wa may be decided automatically by the controller 130 or may be decided manually by the operator.

Then, in the process T5, if it is decided that the after-restart grinding on the wafer Wa is not required, the wafer Wa is transferred to the cassette C to be recovered. When the wafer Wa is recovered in the cassette C without performing the after-restart grinding as described above, the wafer Wa may vary in thickness depending on the state of the wafer Wa. Therefore, in order to stabilize the transfer of the wafer Wa, it is desirable that the thickness (height) of the wafer Wa held on the chuck 31 need to be measured by the inspection unit 120 (height gauges 122 and 123). Alternatively, the wafer Wa may be recovered by the operator.

In the process T5, if it is decided that the after-restart grinding on the wafer Wa is required, whether or not to perform a warm-up (a first preparation processing in the present disclosure) of the processing apparatus 1 is decided (process T6 in FIG. 4). The warm-up is performed for each of the processing positions A1 to A3 where the after-restart grinding is performed. In the following description, the warm-up may be referred to as “sole warm-up”. Whether or not to perform the sole warm-up may be decided automatically by the controller 130 or may be decided manually by the operator. In the process T6, if it is decided that the sole warm-up is not required, the sole warm-up is skipped and the after-restart grinding in the following process T8 is performed.

In the process T6, if it is decided that the sole warm-up is required, the sole warm-up is performed (process T7 in FIG. 4). In the sole warm-up, for example, the temperatures of the chuck 31 and the grinders 91, 101 and 111 are stabilized by allowing water to flow to the grinders 91, 101 and 111 toward the chuck 31 while rotating the grinders 91, 101 and 111 and the chuck 31. Further, the sole warm-up is performed according to a warm-up recipe that defines the flow rate of water and the rotation number. By performing the sole warm-up as described above, the temperatures of the chuck 31 and the grinders 91, 101 and 111 can be kept constant, and, thus, the after-restart grinding in the following process T8 can be performed stably.

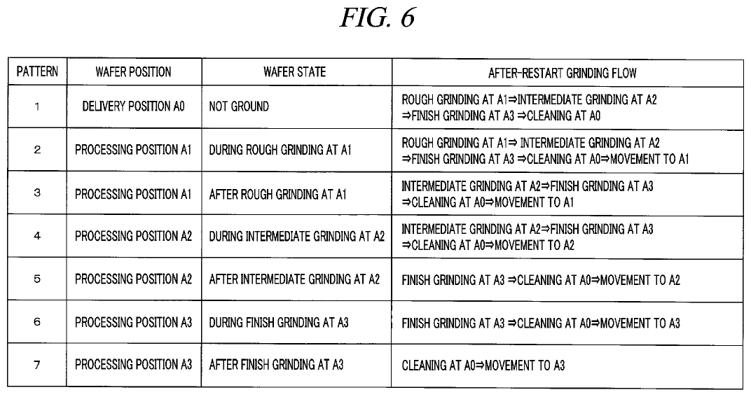

Then, the after-restart grinding is performed on the processing surface Wg of the wafer Wa (process T8 in FIG. 4). The flow of the after-restart grinding varies depending on the position and the state of the wafer Wa. The position of the wafer Wa is a position where the wafer Wa exists and is one of the delivery position A0 and the processing positions A1 to A3. The state of the wafer Wa refers to the final processing state of the wafer Wa when the processing apparatus 1 is shut down. Hereinafter, as shown in FIG. 6, the after-restart grinding will be described by Patterns 1 to 7.

Pattern 1 refers to a case where the position of the wafer Wa is the delivery position A0 and the state of the wafer Wa is “before ground”. In Pattern 1, the rough grinding at the first processing position A1 (process S2), the intermediate grinding at the second processing position A2 (process S3), the finish grinding at the third processing position A3 (process S4) and the processing surface rough cleaning at the delivery position A0 (process S5) are sequentially performed.

Pattern 2 refers to a case where the position of the wafer Wa is the first processing position A1 and the state of the wafer Wa is “during the rough grinding”. Pattern 2 also includes a case where the wafer Wa is not ground at the first processing position A1. First, in Pattern 2, a grinding subsequent to the rough grinding is performed at the first processing position A1. Here, the processing surface Wg of the wafer Wa is ground based on the processing state of the wafer Wa and the grinding recipe stored in the controller 130 when the processing apparatus 1 is shut down in the process T1. For example, a target height of the wafer Wa after the rough grinding is determined in the grinding recipe, and when the processing surface Wg of the wafer Wa is ground to the target height, the rough grinding is ended (process S2). Then, the intermediate grinding at the second processing position A2 (process S3), the finish grinding at the third processing position A3 (process S4), and the processing surface rough cleaning at the delivery position A0 (process S5) are sequentially performed. Thereafter, the wafer Wa is returned back to the first processing position A1, i.e., the position of the wafer Wa when the processing apparatus 1 is shut down.

Further, in Pattern 2, after the processing surface cleaning at the delivery position A0 is ended, it is considered that the wafer Wa may be directly recovered into the cassette C. However, the wafer Wa on which the rough grinding is temporarily stopped and then the after-restart grinding is performed has not been subjected to the normal grinding, and, thus, the quality thereof cannot be guaranteed. Therefore, it is desirable that the wafer Wa need to be returned back to the position (the first processing position A1) at the time when the processing apparatus 1 is shut down and then recovered into the cassette C. Further, basically, it is desirable that the wafer Wa is required to be transferred in the same order in the case where the wafer Wa is transferred into the processing apparatus 1. From this point of view, it is desirable that the wafer Wa need to be returned back to the first processing position A1.

Pattern 3 refers to a case where the position of the wafer Wa is the first processing position A1 and the state of the wafer Wa is “after the rough grinding”. In Pattern 3, the wafer Wa is moved to the second processing position A2 and the intermediate grinding (process S3) is performed on the wafer Wa. Subsequently, the finish grinding at the third processing position A3 (process S4) and the processing surface rough cleaning at the delivery position A0 (process S5) are sequentially performed. Thereafter, the wafer Wa is returned back to the first processing position A1, i.e., the position of the wafer Wa when the processing apparatus 1 is shut down.

Pattern 4 refers to a case where the position of the wafer Wa is the second processing position A2 and the state of the wafer Wa is “during the intermediate grinding”. Pattern 4 also includes a case where the wafer Wa is not ground at the second processing position A2. First, in Pattern 4, a grinding subsequent to the intermediate grinding is performed at the second processing position A2. Here, the processing surface Wg of the wafer Wa is ground based on the processing state of the wafer Wa and the grinding recipe stored in the controller 130 when the processing apparatus 1 is shut down in the process T1, and the intermediate grinding is ended (process S3). Then, the finish grinding at the third processing position A3 (process S4) and the processing surface rough cleaning at the delivery position A0 (process S5) are sequentially performed. Thereafter, the wafer Wa is returned back to the second processing position A2, i.e., the position of the wafer Wa when the processing apparatus 1 is shut down.

Pattern 5 refers to a case where the position of the wafer Wa is the second processing position A2 and the state of the wafer Wa is “after the intermediate grinding”. In Pattern 5, the wafer Wa is moved to the third processing position A3 and the finish grinding (process S4) is performed. Subsequently, the processing surface rough cleaning at the delivery position A0 (process S5) is performed. Thereafter, the wafer Wa is returned back to the second processing position A2, i.e., the position of the wafer Wa when the processing apparatus 1 is shut down.

Pattern 6 refers to a case where the position of the wafer Wa is the third processing position A3 and the state of the wafer Wa is “during the finish grinding”. Pattern 6 also includes a case where the wafer Wa is not ground at the third processing position A3. First, in Pattern 6, a grinding subsequent to the finish grinding is performed at the third processing position A3. Here, the processing surface Wg of the wafer Wa is ground based on the processing state of the wafer Wa and the grinding recipe stored in the controller 130 when the processing apparatus 1 is shut down in the process T1, and the finish grinding is ended (process S4). Then, processing surface rough cleaning at the delivery position A0 (process S5) is performed. Thereafter, the wafer Wa is returned back to the third processing position A3, i.e., the position of the wafer Wa when the processing apparatus 1 is shut down.

Pattern 7 refers to a case where the position of the wafer Wa is the third processing position A3 and the state of the wafer Wa is “after the finish grinding”. In Pattern 5, the wafer Wa is moved to the delivery position A0 and the processing surface cleaning (process S5) is performed. Thereafter, the wafer Wa is returned back to the third processing position A3, i.e., the position of the wafer Wa when the processing apparatus 1 is shut down.

In the above-described example, Patterns 1 to 7 are individually described, but for example, if there is a plurality of wafers Wa at the delivery position A0 and the processing positions A1 to A3, the controller 130 may determine from which position the wafer Wa is to be subjected to the after-restart grinding. Specifically, based on the final processing state of the wafers Wa when the processing apparatus 1 is shut down, the controller 130 automatically sets the order of the after-restart grinding on the wafers Wa. If there is a plurality of wafers Wa as described above, any one of the patterns may be performed in parallel. In other words, the after-restart grinding may be performed on a single sheet of wafer Wa or may be performed in parallel at a plurality of processing positions A1 to A3.

As described above, when the after-restart grinding on the processing surface Wg of the wafer Wa in the process T8 is completed, the wafer Wa on which the after-restarting grinding is completed is transferred to the cassette C to be recovered (process T9 in FIG. 4). Here, before the wafer Wa is transferred to the cassette C, the non-processing surface cleaning in the second cleaning unit 70 (process S6) and the processing surface finish cleaning in the first cleaning unit 60 (process S7) are sequentially performed. In the process T9, after the wafer Wa is recovered and there is no wafer Wa held on the chuck 31, the after-restart grinding on the wafer Wb in the following process T11 is performed, and, thus, a normal warm-up (a second preparation processing in the present disclosure) may be performed. In this warm-up, in addition to the above-described sole warm-up, water or gas is allowed to flow from the chuck 31 or the height of the chuck 31 is adjusted. Also, if a device (for example, mounter) configured to perform a processing subsequent to the grinding is connected to the processing apparatus 1, the wafer Wa may be moved to the corresponding device configured to perform the subsequent processing.

If the controller 130 stores the presence of the wafer Wb in the alignment unit 50 in the process T1, whether to perform the after-restart grinding on the wafer Wb or whether to recover the wafer Wb without performing the after-restart grinding is designated (process T10 in FIG. 4). Whether or not to perform the after-restart grinding on the wafer Wb may be decided automatically by the controller 130 or may be decided manually by the operator. Then, in the process T10, if it is decided that the after-restart grinding on the wafer Wb is not required, the wafer Wb is transferred to the cassette C to be recovered. Alternatively, the wafer Wb may be recovered by the operator. The process T10 may be performed before the process T9.

Then, the after-restart grinding is performed on the wafer Wb which has been decided to be subjected to the after-restart grinding in the process T10 (process T11 in FIG. 4). Specifically, first, in the alignment unit 50, the orientation of the horizontal direction of the wafer Wb is readjusted (process S1). Subsequently, the rough grinding at the first processing position A1 (process S2), the intermediate grinding at the second processing position A2 (process S3), and the finish grinding at the third processing position A3 (process S4) and the processing surface rough cleaning at the delivery position A0 (process S5) are sequentially performed on the wafer Wb. The after-restart grinding on the wafer Wb in the process T11 may be performed in parallel with the recovery of the wafer Wa in the process T9.

Thereafter, the wafer Wb, on which the after-restart grinding is completely performed in the process T11, is transferred to the cassette C to be recovered (process T12 in FIG. 4). Here, before the wafer Wb is transferred to the cassette C, the non-processing surface cleaning in the second cleaning unit 70 (process S6) and the processing surface finish cleaning in the first cleaning unit 60 (process S7) are sequentially performed.

Then, when all the wafers W in the processing apparatus 1 are recovered, whether or not to perform the normal warm-up (the second preparation processing in the present disclosure) of the processing apparatus 1 is designated (process T13 in FIG. 4). Whether or not to perform the warm-up may be decided automatically by the controller 130 or may be decided manually by the operator. Then, in the process T13, if it is decided that the warm-up is not required, the warm-up is skipped and the preparation for performing the normal operation of the processing apparatus 1 is completed.

In the process T13, if it is decided that the warm-up is required, the warm-up is performed (process T14 in FIG. 4). In this warm-up, similarly to the sole warm-up in the process T7, the temperatures of the chuck 31 and the grinders 91, 101 and 111 are stabilized by allowing water or gas to flow to the chuck 31 and the grinders 91, 101 and 111 while rotating the chuck 31 and the grinders 91, 101 and 111. In addition, water or gas is allowed to flow from the chuck 31 or the height of the chuck 31 is adjusted. When the warm-up is completed, the preparation for performing the normal operation of the processing apparatus 1 is completed.

According to the above-described exemplary embodiment, after the processing apparatus 1 is restarted, the after-restart grinding is performed in the process T8 on the wafer Wa detected in the process T4 and decided to be subjected to the after-restart grinding in the process T5. Further, the after-restart grinding is performed in the process T11 on the wafer Wb determined to be subjected to the after-restart grinding in the process T10. For this reason, the wafers Wa and Wb remaining in the processing apparatus 1 when the processing apparatus 1 is shut down can be effectively used without being wasted.

In the process T8, the after-restart grinding is performed on the processing surface Wg of the wafer Wa as in, for example, Patterns 1 to 7 depending on the position and the state of the wafer Wa. Here, the processing surface Wg of the wafer Wa is ground based on the processing state of the wafer Wa and the grinding recipe stored in the controller 130 when the processing apparatus 1 is shut down, and, thus, the after-restart grinding can be appropriately performed.

Further, in the process T8, after after-restart grinding is performed on the processing surface Wg of the wafer Wa, the wafer Wa is returned back to the position at the time of the shutdown of the processing apparatus 1. For this reason, the wafer Wa can be smoothly recovered based on the recipe applied before the shutdown of the processing apparatus 1.

Since the sole warm-up is performed in the process T7, the temperatures of the chuck 31 and the grinders 91, 101 and 111 are stabilized. As a result, the after-restart grinding in the process T8 can be stably performed.

In the process T4, the wafer Wa on the chuck 31 is detected based on the wafer Wa detected by the inspection unit 120 and the state of the wafer Wa stored in the controller 130 at the time of the shutdown of the processing apparatus 1 in the process T1. Since the presence or absence of the wafer Wa is detected using both the controller 130 and the inspection unit 120 as described above, the subsequent processing can be appropriately performed. Specifically, processing conditions for the subsequent processing can be appropriately adjusted, and unnecessary operations, such as performing a processing even when there is no wafer Wa, can be eliminated.

In the process T2, the initialization is sequentially performed according to the function of each unit in the processing apparatus 1. Therefore, each unit can be appropriately initialized.

The exemplary embodiments disclosed herein are illustrative and do not limit the present disclosure. Further, the above-described exemplary embodiments may be omitted, substituted, or changed in various forms without departing from the scope and spirit of the appended claims.

### EXPLANATION OF CODES

1: Processing apparatus
31: Chuck
40: Transfer unit
90: Rough grinding unit
100: Intermediate grinding unit
110: Finish grinding unit
130: Controller
W, Wa, Wb: Wafer

1. A processing apparatus configured to process a substrate, comprising:
a holder configured to hold a substrate;
a grinding device configured to perform a grinding on a processing surface of the substrate held on the holder;
a transfer device configured to transfer the substrate to the holder; and
a controller configured to control the holder, the grinding device and the transfer device,
wherein the controller controls the holder, the grinding device and the transfer device to perform:
performing initialization of the holder, initialization of the grinding device and initialization of the transfer device after the processing apparatus is stopped during an operation thereof and the processing apparatus is restarted;
detecting the substrate on the holder;
deciding whether the grinding on the detected substrate by the grinding device is required; and
performing, by the grinding device, the grinding on the processing surface of the substrate on which the grinding is decided to be required.

2. The processing apparatus of claim 1, further comprising:
a detector configured to detect the substrate held on the holder,
wherein the controller stores therein a state of the substrate on the holder when the processing apparatus is stopped, and
in detecting the substrate on the holder, the controller detects the substrate on the holder based on the state of the substrate when the processing apparatus is stopped, which is stored in the controller, and a detection result by the detector, and the controller decides whether the grinding is required.

3. The processing apparatus of claim 1,
wherein the controller stores therein a state of the substrate on the holder when the processing apparatus is stopped, and
when the substrate on the holder is detected, the controller decides that the grinding on the substrate is required based on the state of the substrate when the processing apparatus is stopped, which is stored in the controller.

4. The processing apparatus of claim 1, further comprising:
a turntable configured to hold multiple holders and configured to be rotated to place the multiple holders at multiple processing positions, the holder having the multiple holders,
wherein the grinding device has multiple grinding devices, and the multiple grinding devices are respectively provided at the multiple processing positions to grind the processing surface of the substrate,
the controller controls the multiple grinding devices and the turntable to consecutively perform the grinding on the processing surface of the substrate by the multiple grinding devices at the multiple processing positions, and
the controller controls the multiple grinding devices and the turntable to move, after the processing surface of the substrate is ground at a first processing position of the multiple processing positions provided next to a second processing position of the multiple processing positions, the substrate to the second processing position by the turntable.

5. The processing apparatus of claim 1,
wherein the controller controls the holder and the grinding device to perform a first preparation processing of the holder and a first preparation processing of the grinding device after deciding whether the grinding is required and before performing the grinding on the processing surface.

6. The processing apparatus of claim 1,
wherein the controller controls the holder and the grinding device to perform a second preparation processing of the holder and a second preparation processing of the grinding device after performing the grinding on the processing surface.

7. The processing apparatus of claim 1, further comprising:
an alignment unit configured to adjust an orientation of a horizontal direction of the substrate before being held on the holder,
wherein the controller controls the alignment unit, the transfer device, the holder and the grinding device to transfer the substrate in the alignment unit to the holder by the transfer device after performing the grinding on the processing surface and to perform the grinding on the processing surface of the substrate held on the holder by the grinding device.

8. The processing apparatus of claim 1,
wherein the controller controls the transfer device, the grinding device and the holder to sequentially perform the initialization of the transfer device, the initialization of the grinding device and the initialization of the holder in the initialization of the holder, the grinding device and the transfer device.

9. A processing method of a substrate using a processing apparatus,
wherein the processing apparatus includes:
a holder configured to hold a substrate;
a grinding device configured to perform a grinding on a processing surface of the substrate held on the holder; and
a transfer device configured to transfer the substrate to the holder, and
wherein the processing method includes:
performing initialization of the holder, initialization of the grinding device and initialization of the transfer device after the processing apparatus is stopped during an operation thereof and the processing apparatus is restarted;
detecting the substrate on the holder;
deciding whether the grinding on the detected substrate by the grinding device is required; and
performing, by the grinding device, the grinding on the processing surface of the substrate on which the grinding is decided to be required.

10. The processing method of claim 9,
wherein the processing apparatus further includes a detector configured to detect the substrate held on the holder,
a state of the substrate on the holder when the processing apparatus is stopped is stored before the performing of the initialization of the holder, the initialization of the grinding device and the initialization of the transfer device, and
in the detecting of the substrate on the holder, the substrate on the holder is detected based on the state of the substrate when the processing apparatus is stopped, which is stored, and a detection result by the detector, and whether the grinding is required is decided.

11. The processing method of claim 9,
wherein a state of the substrate on the holder when the processing apparatus is stopped is stored before the performing of the initialization of the holder, the initialization of the grinding device and the initialization of the transfer device, and
in the detecting of the substrate on the holder, when the substrate on the holder is detected, it is decided based on the state of the substrate when the processing apparatus is stopped, which is stored, that the grinding on the substrate is required.

12. The processing method of claim 9,
wherein the holder has multiple holders, and the processing apparatus further includes a turntable configured to hold the multiple holders and configured to be rotated to place the multiple holders at multiple processing positions,
the grinding device has multiple grinding devices, and the multiple grinding devices are respectively provided the multiple processing positions to grind the processing surface of the substrate, and
in the performing of the grinding on the processing surface, the processing surface of the substrate is consecutively ground by the multiple grinding devices at the multiple processing positions, and after the processing surface of the substrate is ground at a first processing position of the multiple processing positions provided next to a second processing position of the multiple processing positions, the substrate is moved to the second processing position by the turntable.

13. The processing method of claim 9,
wherein a first preparation processing of the holder and a first preparation processing of the grinding device are performed after the deciding of whether the grinding is required and before the performing of the grinding on the processing surface.

14. The processing method of claim 9,
wherein a second preparation processing of the holder and a second preparation processing of the grinding device are preformed after the performing of the grinding on the processing surface.

15. The processing method of claim 9,
wherein the processing apparatus further includes an alignment unit configured to adjust an orientation of a horizontal direction of the substrate before being held on the holder, and
after the performing of the grinding on the processing surface, the substrate in the alignment unit is transferred to the holder by the transfer device, and the processing surface of the substrate held on the holder is ground by the grinding device.

16. The processing method of claim 9,
wherein the initialization of the transfer device, the initialization of the grinding device and the initialization of the holder are sequentially performed in the initialization of the holder, the grinding device and the transfer device.

17. A computer-readable recording medium having stored computer-executable instructions that, in response to execution, cause a processing apparatus to perform a processing method of claim 9.
